(19) United States
(12) Patent Application Publication
(10) Pub. No.: US 2021/0215435 A1
(43) Pub. Date: Jul. 15, 2021

(54) VAPOR CHAMBER

(71) Applicant: Auras Technology Co., Ltd., New Taipei City (TW)

(72) Inventors: Chih-Wei CHEN, New Taipei City (TW); Tien-Yao CHANG, New Taipei City (TW); Che-Wei KUO, New Taipei City (TW); Zi-Yun JIAN, New Taipei City (TW)

(21) Appl. No.: 17/111,021

(22) Filed: Dec. 3, 2020

(30) Foreign Application Priority Data
Jan. 10, 2020 (TW) 109100917

(51) Int. Cl. F28D 15/04; F28D 15/02; H05K 7/20

(52) U.S. Cl. CPC F28D 15/046; H05K 7/20336; F28D 15/0233

(57) ABSTRACT

The present disclosure provides a vapor chamber including an upper plate and a lower plate. The upper plate includes a first metal layer and a second metal layer made of different materials. The lower plate is attached to the upper plate. A stamping process is performed on the first metal layer and the second metal layer of the upper plate, so that the first metal layer and the second metal layer are simultaneously deformed to form at least one supporting structure and a first skirt structure. The upper plate is attached to the lower plate via the first skirt structure to define a working space. At least one supporting structure is within the working space.

### RELATED APPLICATIONS

This application claims priority to Taiwan Application Serial Number 109100917, filed Jan. 10, 2020, which is herein incorporated by reference.

### BACKGROUND

### Field of Invention

The present disclosure relates to a heat dissipation device, in particular to a vapor chamber.

### Description of Related Art

The statements in this section merely provide background information related to the present disclosure and do not necessarily constitute prior art.

Vapor chamber is one type of heat dissipating device. The working principle of the vapor chamber is similar to that of the heat pipe. The difference between the vapor chamber and the heat pipe is that the heat conduction of the heat pipe is transmitted in one-dimensional (line) direction, while the heat conduction of the vapor chamber is transmitted in two-dimensional (surface) direction. In terms of structure, the vapor chamber is mainly constituted by an upper plate body, a lower plate body, and a working space. When the lower plate body is in contact with a heat source such as a heat-generating electronic component, the working medium in the working space will be converted from liquid to gas and transmitted to the upper plate body. Finally, heat energy is transmitted out by an area of the vapor chamber other than an area that contacts the heat source or a heat sink (such us fins) outside the vapor chamber. At the time, the working medium will be converted back to the liquid state and return to the lower plate body, and the next cycle will be started and repeated.

Nowadays, hand-held electronic devices such as smartphones, tablet computers, or small notebook computers are mainstream products in the market. The hand-held electronic devices as mentioned mainly use thin vapor chambers to achieve heat dissipation of internal electronic components. However, since the thin vapor chamber is prone to deformation, especially when the vapor chamber is attached to the heat source during the assembly operation. Therefore, how to improve the structural strength of the vapor chamber without hindering the normal operation of the vapor chamber is the focus of skilled persons in the field.

### SUMMARY

One of the objectives of the present disclosure is to provide a vapor chamber, in which an upper plate and a lower plate of the vapor chamber are mainly composite metal plates made of at least two different metal materials. Supporting structures and a skirt structure are directly formed on the upper plate or the lower plate by a stamping process or an etching process, so as to ensure normal operation of the vapor chamber while improving its structural strength and reliability.

Other objectives and advantages of the present disclosure can be further understood by technical features disclosed in the present disclosure.

To achieve one, part, or all of the above purposes, or other purposes, the present disclosure provides a vapor chamber which includes an upper plate and a lower plate. The upper plate includes a first metal layer and a second metal layer made of different materials. The lower plate is attached to the upper plate. A stamping process is performed on the first metal layer and the second metal layer of the upper plate, so that the first metal layer and the second metal layer are simultaneously deformed to form at least one supporting structure and a first skirt structure. The upper plate is attached to the lower plate via the first skirt structure to define a working space. At least one supporting structure is within the working space.

In one embodiment of the present disclosure, the first metal layer and the second metal layer of the upper plate as mentioned are joined to one another by diffusion bonding.

In one embodiment of the present disclosure, the lower plate as mentioned includes a third metal layer and a fourth metal layer made of different materials, and an etching process is performed on the third metal layer to form a second skirt structure on the third metal layer. The lower plate is attached to the first skirt structure of the upper plate via the second skirt structure to define the working space.

In one embodiment of the present disclosure, the third metal layer and the fourth metal layer of the lower plate as mentioned are joined to one another by diffusion bonding.

In one embodiment of the present disclosure, the first skirt structure defines a first space, the second skirt structure defines a second space, and the working space comprises the first space and the second space.

In one embodiment of the present disclosure, a capillary structure is formed on the third metal layer of the lower plate. The capillary structure is within the working space, and at least one supporting structure is in contact with the capillary structure.

In one embodiment of the present disclosure, the first metal layer is between the second metal layer and the third metal layer. A thickness of the second metal layer is greater than or equal to one-fourth of a thickness of the first metal layer, and the thickness of the second metal layer is smaller than or equal to one-third of the thickness of the first metal layer. The third metal layer is between the first metal layer and the fourth metal layer. A thickness of the fourth metal layer is greater than or equal to one-fourth of a thickness of the third metal layer, and the thickness of the fourth metal layer is smaller than or equal to one-third of the thickness of the third metal layer.

In one embodiment of the present disclosure, metal strength of the second metal layer is greater than metal strength of the first metal layer, and metal strength of the fourth metal layer is greater than metal strength of the third metal layer.

In another aspect, the present disclosure provides a vapor chamber including an upper plate and a lower plate. The upper plate includes a first metal layer and a second metal layer made of different materials. The lower plate is attached to the upper plate. A stamping process is performed on the first metal layer of the upper plate, so that the first metal layer is deformed to form at least one supporting structure and a first skirt structure. The upper plate is attached to the lower plate via the first skirt structure to define a working space. At least one supporting structure is within the working space.

In another aspect, the present disclosure provides a vapor chamber including an upper plate and a lower plate. The upper plate includes a first metal layer and a second metal layer made of different materials. The lower plate includes a third metal layer and a fourth metal layer made of different materials. A stamping process is performed on the first metal layer and the second metal layer of the upper plate, so that the first metal layer and the second metal layer are simultaneously deformed to form a first skirt structure. An etching process is performed on the third metal layer of the lower plate to form a second skirt structure and at least one supporting structure on the third metal layer. The lower plate is attached to the first skirt structure of the upper plate via the second skirt structure to define a working space. At least one supporting structure is within the working space.

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a schematic cross-sectional view of a vapor chamber according to an embodiment of the present disclosure.

FIGS. 2A to 2F are schematic diagrams of the manufacturing process of the vapor chamber as shown in FIG. 1.

FIG. 3 is a schematic cross-sectional view of a vapor chamber according to another embodiment of the present disclosure.

FIG. 4 is a schematic cross-sectional view of a vapor chamber according to still another embodiment of the present disclosure.

FIGS. 5A to 5F are schematic diagrams of the manufacturing process of the vapor chamber as shown in FIG. 4.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts.

In various embodiments, the description is made with reference to figures. However, certain embodiments may be practiced without one or more of these specific details, or in combination with other known methods and configurations. In the following description, numerous specific details are set forth, such as specific configurations, dimensions, and processes, etc., in order to provide a thorough understanding of the present disclosure. Reference throughout this specification to “one embodiment,” “an embodiment” or the like means that a particular feature, structure, configuration, or characteristic described in connection with the embodiment is included in at least one embodiment of the disclosure. Thus, the appearances of the phrase “in one embodiment,” “in an embodiment” or the like in various places throughout this specification are not necessarily referring to the same embodiment of the disclosure. Furthermore, the particular features, structures, configurations, or characteristics may be combined in any suitable manner in one or more embodiments.

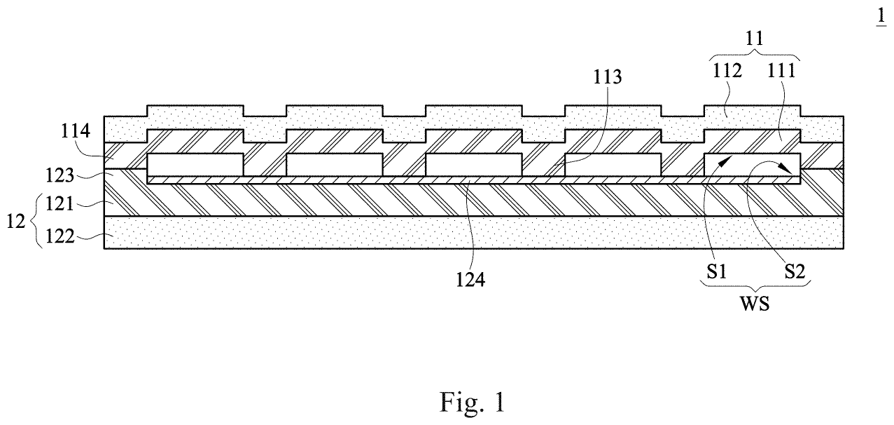

Reference is made to FIG. 1, which is a schematic cross-sectional view of a vapor chamber according to an embodiment of the present disclosure. As shown in FIG. 1, a vapor chamber 1 in the present embodiment includes an upper plate 11 and a lower plate 12. The upper plate 11 includes a first metal layer 111 and a second metal layer 112 made of different materials. The lower plate 12 is attached to the upper plate 11. In the present embodiment, the upper plate 11 has a plurality of supporting structures 113 and a first skirt structure 114. The supporting structures 113 extend towards the lower plate 12. The supporting structures 113 are arranged at intervals. The upper plate 11 is attached to the lower plate 12 via the first skirt structure 114, and a working space WS is defined between the upper plate 11 and the lower plate 12. The supporting structures 113 as mentioned are within the working space WS, and the working space WS is filled with working medium. Specifically, the supporting structures 113 and the first skirt structure 114 of the upper plate 11 are formed by a stamping process. That is, the first metal layer 111 and the second metal layer 112 of the upper plate 11 are stamped, so that the first metal layer 111 and the second metal layer 112 are simultaneously deformed to form the supporting structures 113 extending towards the lower plate 12, and to form the first skirt structure 114. The heat dissipation principle and the operation of the vapor chamber 1 are well known to those skilled in the art, and will not be illustrated herein.

Detailed structures of the vapor chamber 1 in the embodiment of the present disclosure will be further described below.

As shown in FIG. 1, the lower plate 12 in the present embodiment includes a third metal layer 121 and a fourth metal layer 122 made of different materials. In the present embodiment, the lower plate 12 has a second skirt structure 123. The lower plate 12 is attached to the first skirt structure 114 of the upper plate 11 via the second skirt structure 123, and the working space WS as mentioned is defined between the lower plate 12 and the upper plate 11. Specifically, the second skirt structure 123 of the lower plate 12 is formed by an etching process. That is, the etching process is performed on the third metal layer 121 of the lower plate 12 to form the second skirt structure 123 as mentioned on the third metal layer 121.

As shown in FIG. 1, when the first metal layer 111 and the second metal layer 112 of the upper plate 11 are stamped to form the plurality of supporting structures 113 and the first skirt structure 114, the first skirt structure 114 defines a first space S1 below the upper plate 11. That is, space between the first skirt structure 114 and the adjacent supporting structures 113 and space between any two adjacent supporting structures 113. When the third metal layer 121 of the lower plate 12 is etched to form the second skirt structure 123, the second skirt structure 123 defines a second space S2 above the lower plate 12. After the first skirt structure 114 of the upper plate 11 and the second skirt structure 123 of the lower plate 12 are attached to one another, the working space WS defined between the first skirt structure 114 and the second skirt structure 123 includes the first space S1 and the second space S2 as mentioned. That is, the first space S1 and the second space S2 are combined to form a complete working space WS.

As shown in FIG. 1, the lower plate 12 of the present embodiment further includes a capillary structure 124. The capillary structure 124 is formed on the third metal layer 121 of the lower plate 12, and the capillary structure 124 is within the working space WS. The supporting structures 113 extended out from the upper plate 11 are in contact with the capillary structure 124. Specifically, after the third metal layer 121 of the lower plate 12 is etched to form the second skirt structure 123, the second skirt structure 123 defines the second space S2 above the lower plate 12. At the time, the capillary structure 124 is formed within the second space S2 of the lower plate 12. After the first skirt structure 114 of the upper plate 11 and the second skirt structure 123 of the lower plate 12 are attached to one another, the supporting structures 113 extended out from the upper plate 11 are in contact with the capillary structure 124.

As shown in FIG. 1, the first metal layer 111 in the present embodiment is between the second metal layer 112 and the third metal layer 121 of the lower plate 12. That is, the first metal layer 111 is an inner metal layer of the upper plate 11, and the second metal layer 112 is an outer metal layer of the upper plate 11. In the present embodiment, a thickness of the second metal layer 112 is, for example, greater than or equal to one-fourth of a thickness of the first metal layer 111, and smaller than or equal to one-third of the thickness of the first metal layer 111. That is, the thickness of the outer metal layer of the upper plate 11 is smaller than the thickness of the inner metal layer of the upper plate 11, and metal strength of the second metal layer 112 is greater than metal strength of the first metal layer 111. In the present embodiment, the third metal layer 121 is between the fourth metal layer 122 and the first metal layer 111 of the upper plate 11. That is, the third metal layer 121 is an inner metal layer of the lower plate 12, and the fourth metal layer 122 is an outer metal layer of the lower plate 12. In the present embodiment, a thickness of the fourth metal layer 122 is, for example, greater than or equal to one-fourth of a thickness of the third metal layer 121 and smaller than or equal to one-third of the thickness of the third metal layer 121. That is, the thickness of the outer metal layer of the lower plate 12 is smaller than the thickness of the inner metal layer of the lower plate 12, and metal strength of the fourth metal layer 122 is greater than metal strength of the third metal layer 121. In addition, the first metal layer 111 and the second metal layer 112 are joined to one another by, for example, diffusion bonding, thereby forming the upper plate 11 having a composite metal layer structure. In the same way, the third metal layer 121 and the fourth metal layer 122 are joined to one another by, for example, diffusion bonding, thereby forming the lower plate 12 having a composite metal layer structure.

It is noted that materials of the first metal layer 111 and the second metal layer 112 of the upper plate 11, and the third metal layer 121 and the fourth metal layer 122 of the lower plate 12 can be respectively selected from one of titanium, nickel, copper, and steel. Under the premise that metal strength of the outer metal layer (the second metal layer 112 and the fourth metal layer 122) is greater than metal strength of the inner metal layer (the first metal layer 111 and the third metal layer 121), the materials of the aforementioned metal layer can be replaced at will. In the present embodiment, the outer metal layer (the second metal layer 112 and the fourth metal layer 122) is, for example, nickel, and the inner metal layer (the first metal layer 111 and the third metal layer 121) is, for example, copper. Furthermore, the present disclosure does not limit the joining method between the first metal layer 111 and the second metal layer 112 and the joining method between the third metal layer 121 and the fourth metal layer 122. The joining method between the first metal layer 111 and the second metal layer 112 and the joining method between the third metal layer 121 and the fourth metal layer 122 may vary according to actual requirements. In addition, the standard for measuring metal strength as mentioned is selected from one of Young's coefficient and Vickers hardness.

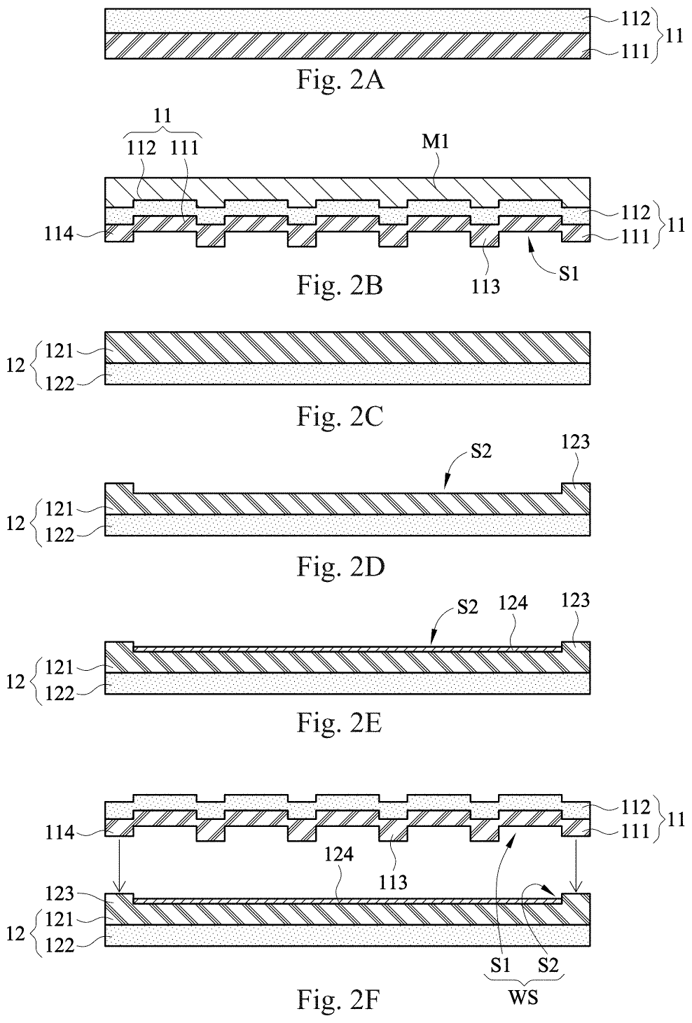

Reference is made to FIGS. 2A to 2F, which are schematic diagrams of the manufacturing process of the vapor chamber as shown in FIG. 1. As shown in FIG. 2A, the upper plate 11 constituted by the first metal layer 111 and the second metal layer 112 is provided. Then, as shown in FIG. 2B, the plurality of supporting structures 113 and the first skirt structure 114 are formed by stamping the first metal layer 111 and the second metal layer 112 by a mold M1. Then, as shown in FIG. 2C, the lower plate 12 constituted by the third metal layer 121 and the fourth metal layer 122 is provided. Then, as shown in FIG. 2D, an etching process is performed on the third metal layer 121 to form the second skirt structure 123 on the third metal layer 121. Then, as shown in FIG. 2E, the capillary structure 124 is formed in the second space S2 of the third metal layer 121. Then, as shown in FIG. 2F, the first skirt structure 114 of the upper plate 11 is attached to the second skirt structure 123 of the lower plate 12 to form the vapor chamber 1 structure as shown in FIG. 1.

It is noted that the sequence of the manufacturing process of the vapor chamber as shown in FIGS. 2A to 2F is only one of the embodiments of the present disclosure. The present disclosure does not limit the sequence of the above manufacturing process for the vapor chamber. For example, the steps in FIGS. 2C to 2E can be performed before the steps in FIGS. 2A to 2B. That is, the manufacture of the lower plate 12 is performed first (such as etching the third metal layer 121 to form the capillary structure 124), and then the manufacture of the upper plate 11 (such as simultaneously stamping the first metal layer 111 and the second metal layer 112) is performed. In other words, the manufactures of the upper plate 11 and the lower plate 12 are two separate and independent processes, and the sequence of completing the two processes does not affect the subsequent step of attaching the upper plate 11 to the lower plate 12 (as shown in FIG. 2F).

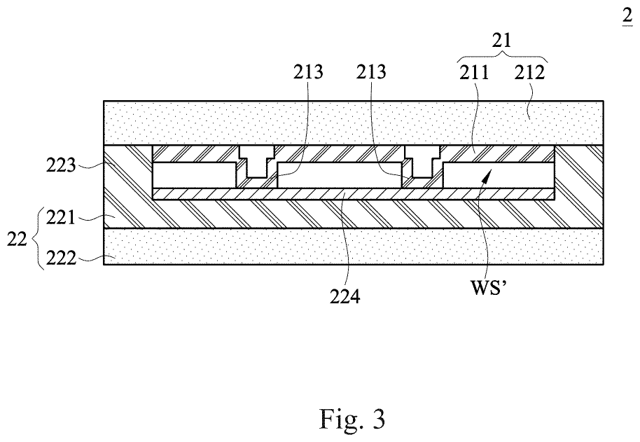

Reference is made to FIG. 3, which is a schematic cross-sectional view of a vapor chamber according to another embodiment of the present disclosure. As shown in FIG. 3, the vapor chamber 2 of the present embodiment includes an upper plate 21 and a lower plate 22. The upper plate 21 includes a first metal layer 211 and a second metal layer 212 made of different materials. The lower plate 22 includes a third metal layer 221 and a fourth metal layer 222 made of different materials. In the present embodiment, the upper plate 21 has a plurality of supporting structures 213 extending towards the lower plate 22. The supporting structures 213 are arranged at intervals. The upper plate 21 is attached to the lower plate 22 via the second metal layer 212, and a working space WS' is defined between the upper plate 21 and the lower plate 22. The supporting structures 213 as mentioned are within the working space WS′, and the working space WS' is filled with working medium. The lower plate 22 has a skirt structure 223. The lower plate 22 is attached to the second metal layer 212 of the upper plate 21 via the skirt structure 223, and a working space WS' is defined by the lower plate 22 and the upper plate 21. That is, the working space WS' in the present embodiment is directly defined by the skirt structure 223 of the lower plate 22.

From the above illustration, the difference between the vapor chamber 2 described in the present embodiment and the vapor chamber 1 as shown in FIG. 1 is that: in the present embodiment, only the inner first metal layer 211 is stamped, and the outer second metal layer 212 is not stamped, so that only the first metal layer 211 is deformed to form the supporting structures 213 extending towards the lower plate 22. Except for the above difference, other detailed structures of the vapor chamber 2 in the present embodiment, such as the skirt structure 223 of the lower plate 22 which is formed by etching and the capillary structure 224 formed on the third metal layer 221 of the lower plate 22, are similar to the vapor chamber 1 as shown in FIG. 1 and will not be repeated again in this paragraph. In addition, the manufacturing process of the vapor chamber 2 in the present embodiment is similar to the manufacturing process as shown in FIGS. 2A to 2F. The only difference is that before the first metal layer 211 and the second metal layer 212 are joined to form the upper plate 21, the first metal layer 211 is stamped.

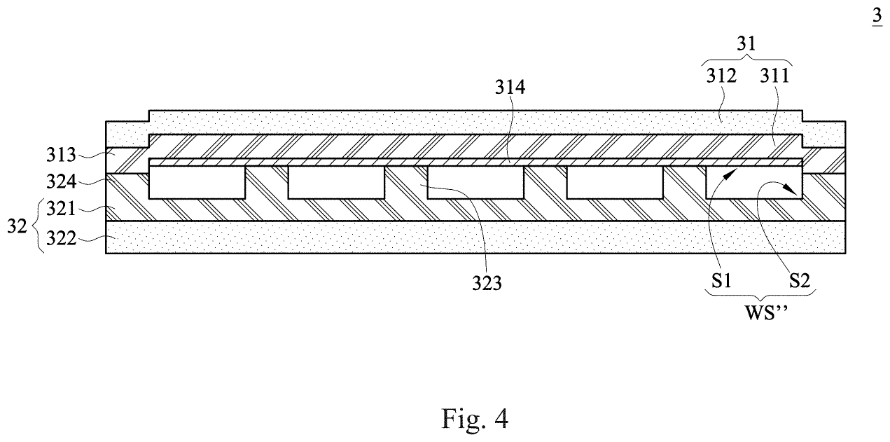

Reference is made to FIG. 4, which is a schematic cross-sectional view of a vapor chamber according to still another embodiment of the present disclosure. As shown in FIG. 4, a vapor chamber 3 of the present embodiment includes an upper plate 31 and a lower plate 32. The upper plate 31 includes a first metal layer 311 and a second metal layer 312 made of different materials. The lower plate 32 includes a third metal layer 321 and a fourth metal layer 332 made of different materials. In the present embodiment, the upper plate 31 has a first skirt structure 313. The lower plate 32 has a plurality of supporting structures 323 and a second skirt structure 324. The supporting structures 323 extend towards the upper plate 31. The supporting structures 323 are arranged at intervals. The lower plate 32 is attached to the first skirt structure 313 of the upper plate 31 via the second skirt structure 324. A working space WS″ is defined between the upper plate 31 and the lower plate 32. The supporting structures 323 as mentioned are within the working space WS″, and the working space WS″ is filled with working medium.

From the above illustration, the difference between the vapor chamber 3 described in the present embodiment and the vapor chamber 1 as shown in FIG. 1 is that: in the present embodiment, the first skirt structure 313 of the upper plate 31 is formed by a stamping process. That is, the first metal layer 311 and the second metal layer 312 of the upper plate 31 are stamped, so that the first metal layer 311 and the second metal layer 312 are simultaneously deformed to form the first skirt structure 313. The supporting structures 323 and the second skirt structure 324 of the lower plate 32 are formed by an etching process. That is, the third metal layer 321 of the lower plate 32 is etched to form the supporting structures 323 and the second skirt structure 324 on the third metal layer 321. In addition, the upper plate 31 of the present disclosure includes a capillary structure 314. The capillary structure 314 is formed on the first metal layer 311 of the upper plate 31. The capillary structure 314 is within the working space WS″ (that is, within the first space S1 defined by the first skirt structure 313). The supporting structures 323 extended out from the lower plate 32 are in contact with the capillary structure 314. Except for the above differences, other detailed structures of the vapor chamber 3 in the present embodiment are similar to that of the vapor chamber 1 as shown in FIG. 1, and will not be repeated in this paragraph.

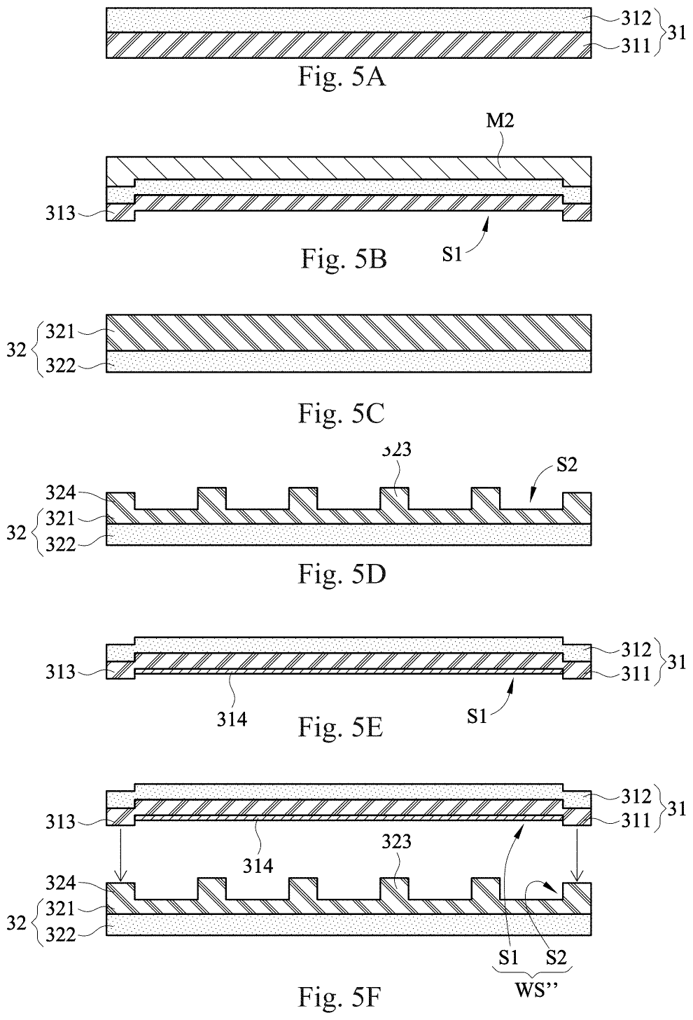

Reference is made to FIGS. 5A to 5F, which are schematic diagrams of the manufacturing process of the vapor chamber as shown in FIG. 4. As shown in FIG. 5A, the upper plate 31 constituted by the first metal layer 311 and the second metal layer 312 is provided. Then, as shown in FIG. 5B, the first skirt structure 313 is formed by stamping the first metal layer 311 and the second metal layer 312 by a mold M2. Then, as shown in FIG. 5C, the lower plate 32 constituted by the third metal layer 321 and the fourth metal layer 322 is provided. Then, as shown in FIG. 5D, an etching process is performed on the third metal layer 321 to form the plurality of supporting structures 323 and the second skirt structure 324 on the third metal layer 321. Then, as shown in FIG. 5E, the capillary structure 314 is formed in the first space S1 of the first metal layer 311. Then, as shown in FIG. 5F, the first skirt structure 313 of the upper plate 31 is attached to the second skirt structure 324 of the lower plate 32 to form the vapor chamber 3 structure as shown in FIG. 4.

It is noted that the sequence of the manufacturing process of the vapor chamber as shown in FIGS. 5A to 5F is only one of the embodiments of the present disclosure. The present disclosure does not limit the sequence of the above manufacturing process for the vapor chamber. For example, the steps in FIGS. 5C to 5D can be performed before the steps in FIGS. 5A to 5B. That is, the manufacture of the lower plate 32 is performed first (such as etching the third metal layer 321), and then the manufacture of the upper plate 31 (such as simultaneously stamping the first metal layer 311 and the second metal layer 312) is performed. In other words, the manufacture of the upper plate 31 and the lower plate 32 are two separate and independent processes, and the sequence of completing the two processes does not affect the subsequent step of attaching the upper plate 31 to the lower plate 32 (as shown in FIG. 5F).

In summary, the upper plate and the lower plate of the vapor chamber in the embodiments of the present disclosure are mainly composite metal plates made of at least two different metal materials. The supporting structures and skirt structure are directly formed on the upper plate or the lower plate by stamping or etching processes, so as to ensure normal operation of the vapor chamber while improving its structural strength and reliability.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the method and the structure of the present disclosure without departing from the scope or spirit of the disclosure. In view of the foregoing, it is intended that the present disclosure cover modifications and variations of this disclosure provided they fall within the scope of the following claims.

What is claimed is:

1. A vapor chamber, comprising:
an upper plate comprising a first metal layer and a second metal layer made of different materials; and
a lower plate attached to the upper plate, wherein a stamping process is performed on the first metal layer and the second metal layer of the upper plate, so that the first metal layer and the second metal layer are simultaneously deformed to form at least one supporting structure and a first skirt structure, the upper plate is attached to the lower plate via the first skirt structure to define a working space, the at least one supporting structure is within the working space.

2. The vapor chamber of claim 1, wherein the first metal layer and the second metal layer of the upper plate are joined to one another by diffusion bonding.

3. The vapor chamber of claim 1, wherein the lower plate comprises a third metal layer and a fourth metal layer made of different materials, and an etching process is performed on the third metal layer to form a second skirt structure on the third metal layer, the lower plate is attached to the first skirt structure of the upper plate via the second skirt structure to define the working space.

4. The vapor chamber of claim 3, wherein the third metal layer and the fourth metal layer of the lower plate are joined to one another by diffusion bonding.

5. The vapor chamber of claim 3, wherein the first skirt structure defines a first space, the second skirt structure defines a second space, and the working space comprises the first space and the second space.

6. The vapor chamber of claim 3, wherein a capillary structure is formed on the third metal layer of the lower plate, the capillary structure is within the working space, and the at least one supporting structure is in contact with the capillary structure.

7. The vapor chamber of claim 3, wherein the first metal layer is between the second metal layer and the third metal layer, a thickness of the second metal layer is greater than or equal to one-fourth of a thickness of the first metal layer, and the thickness of the second metal layer is smaller than or equal to one-third of the thickness of the first metal layer, the third metal layer is between the first metal layer and the fourth metal layer, a thickness of the fourth metal layer is greater than or equal to one-fourth of a thickness of the third metal layer, and the thickness of the fourth metal layer is smaller than or equal to one-third of the thickness of the third metal layer.

8. The vapor chamber of claim 7, wherein metal strength of the second metal layer is greater than metal strength of the first metal layer, and metal strength of the fourth metal layer is greater than metal strength of the third metal layer.

9. A vapor chamber, comprising:
an upper plate comprising a first metal layer and a second metal layer made of different materials; and
a lower plate attached to the upper plate, wherein a stamping process is performed on the first metal layer of the upper plate, so that the first metal layer is deformed to form at least one supporting structure, the upper plate is attached to the lower plate via the second metal layer to define a working space, the at least one supporting structure is within the working space.

10. The vapor chamber of claim 9, wherein the first metal layer and the second metal layer of the upper plate are joined to one another by diffusion bonding.

11. The vapor chamber of claim 9, wherein the lower plate comprises a third metal layer and a fourth metal layer made of different materials, and an etching process is performed on the third metal layer of the lower plate to form a skirt structure on the third metal layer, the lower plate is attached to the second metal layer of the upper plate via the skirt structure to define the working space.

12. The vapor chamber of claim 11, wherein the third metal layer and the fourth metal layer of the lower plate are joined to one another by diffusion bonding.

13. The vapor chamber of claim 11, wherein the skirt structure of the lower plate defines the working space.

14. The vapor chamber of claim 11, wherein a capillary structure is formed on the third metal layer of the lower plate, the capillary structure is within the working space, and the at least one supporting structure is in contact with the capillary structure.

15. The vapor chamber of claim 11, wherein the first metal layer is between the second metal layer and the third metal layer, a thickness of the second metal layer is greater than or equal to one-fourth of a thickness of the first metal layer, and the thickness of the second metal layer is smaller than or equal to one-third of the thickness of the first metal layer, the third metal layer is between the first metal layer and the fourth metal layer, a thickness of the fourth metal layer is greater than or equal to one-fourth of a thickness of the third metal layer, and the thickness of the fourth metal layer is smaller than or equal to one-third of the thickness of the third metal layer.

16. The vapor chamber of claim 15, wherein metal strength of the second metal layer is greater than metal strength of the first metal layer, and metal strength of the fourth metal layer is greater than metal strength of the third metal layer.

17. A vapor chamber, comprising:
an upper plate comprising a first metal layer and a second metal layer made of different materials; and
a lower plate comprising a third metal layer and a fourth metal layer made of different materials, wherein a stamping process is performed on the first metal layer and the second metal layer of the upper plate, so that the first metal layer and the second metal layer are simultaneously deformed to form a first skirt structure, and wherein an etching process is performed on the third metal layer of the lower plate to form a second skirt structure and at least one supporting structure on the third metal layer, the lower plate is attached to the first skirt structure of the upper plate via the second skirt structure to define a working space, the at least one supporting structure is within the working space.

18. The vapor chamber of claim 17, wherein the first metal layer and the second metal layer of the upper plate are joined to one another by diffusion bonding, and the third metal layer and the fourth metal layer of the lower plate are joined to one another by diffusion bonding.

19. The vapor chamber of claim 17, wherein the first skirt structure defines a first space, the second skirt structure defines a second space, and the working space comprises the first space and the second space.

20. The vapor chamber of claim 17, wherein a capillary structure is formed on the first metal layer of the upper plate, the capillary structure is within the working space, and the at least one supporting structure is in contact with the capillary structure.

21. The vapor chamber of claim 17, wherein the first metal layer is between the second metal layer and the third metal layer, a thickness of the second metal layer is greater than or equal to one-fourth of a thickness of the first metal layer, and the thickness of the second metal layer is smaller than or equal to one-third of the thickness of the first metal layer, the third metal layer is between the first metal layer and the fourth metal layer, a thickness of the fourth metal layer is greater than or equal to one-fourth of a thickness of the third metal layer, and the thickness of the fourth metal layer is smaller than or equal to one-third of the thickness of the third metal layer.

22. The vapor chamber of claim 21, wherein metal strength of the second metal layer is greater than metal strength of the first metal layer, and metal strength of the fourth metal layer is greater than metal strength of the third metal layer.
